(19) United States
(12) Patent Application Publication
(10) Pub. No.: US 2025/0380621 A1
(43) Pub. Date: Dec. 11, 2025

(54) SEMICONDUCTOR DEVICE AND METHOD FOR MANUFACTURING THE SAME

(71) Applicant: RESEARCH & BUSINESS FOUNDATION SUNGKYUNKWAN UNIVERSITY, Gyeonggi-do (KR)

(72) Inventors: Woo Jong YU, Suwon-si (KR); Yong Ha SHIN, Gunpo-si (KR)

(73) Assignee: RESEARCH & BUSINESS FOUNDATION SUNGKYUNKWAN UNIVERSITY, Gyeonggi-do (KR)

(21) Appl. No.: 19/047,189

(22) Filed: Feb. 6, 2025

(30) Foreign Application Priority Data
Jun. 10, 2024 (KR) 10-2024-0075057

(51) Int. Cl. H10N 70/20; H10D 62/80; H10N 70/00

(52) U.S. Cl. CPC H10N 70/235; H10D 62/883; H10N 70/021; H10N 70/841; H10N 70/882

(57) ABSTRACT

Provided is a semiconductor device including a substrate, an insulating layer on the substrate, a phase change material structure on the insulating layer, and a first source/drain electrode and a second source/drain electrode disposed on the phase change material structure and spaced apart from each other in a first direction, wherein the phase change material structure includes a plurality of two-dimensional material layers, and an intercalation material between the plurality of two-dimensional material layers.

### CROSS-REFERENCE TO RELATED APPLICATIONS

This U.S. non-provisional patent application claims priority under 35 U.S.C. § 119 of Korean Patent Application No. 10-2024-0075057, filed on Jun. 10, 2024, the entire contents of which are hereby incorporated by reference.

### BACKGROUND

This research was conducted with the support of Samsung Science & Technology Foundation (Project No. SRFC-MA1701-52/Project Name: Ferroelectric-Phase Transition Material-Based Van der Waals Heterostructure Neuristor Integrated Circuit).

The present disclosure herein relates to a semiconductor device and a method for manufacturing the same, and more particularly, to a semiconductor device including a phase change material layer and a method for manufacturing the same.

The highly advanced modern industry is driving a growing pursuit of highly integrated semiconductor devices. In particular, in areas such as artificial intelligence (AI) and machine learning, semiconductor devices enabling in-memory computing are required and, to this end, developing highly integrated semiconductor devices providing high-speed data processing with low power consumption is ever more needed. To meet these requirements, research on semiconductor devices exploiting phase transitions like amorphous-crystalline transition has been ongoing, yet still further research and development are called for to enable the commercial use of phase change semiconductor devices in the industry.

The semiconductor elements employing phase change may include two-dimensional materials (2D materials) and, for example, the two-dimensional materials may be two-dimensional transition metal compounds or two-dimensional transition metal dichalcogenides. The two-dimensional transition metal compounds or two-dimensional transition metal dichalcogenides (TMDs) are single-layer or multi-layer solids in which atoms form a specific crystal structure, and have these high surface area characteristics to be utilized in various electrical applications such as field effect transistors, LEDs, solar cells, and memristors. However, in the application of the two-dimensional materials to semiconductor devices, there are multiple technical challenges to overcome, and excellent characteristics and performance may not be achievable.

As a nonvolatile memory device, a memristor contains a number of memory cells capable of retaining information even when power is off, allowing the stored information to be used again once power is restored. The memristor is applicable to mobile phones, digital cameras, personal digital assistants (PDAs), mobile computer devices, stationary computer devices, and other devices.

### SUMMARY

The present disclosure provides a semiconductor device having improved electrical characteristics and reliability.

The present disclosure also provides a method for manufacturing a semiconductor device having improved electrical characteristics and reliability.

The present disclosure also provides a synaptic element exhibiting synaptic plasticity.

The present disclosure is not limited to the technical problems described above, and those skilled in the art may understand other technical problems from the following description.

An embodiment of the inventive concept provides a semiconductor device including a substrate, an insulating layer on the substrate, a phase change material structure on the insulating layer, and a first source/drain electrode and a second source/drain electrode disposed on the phase change material structure and spaced apart from each other in a first direction, wherein the phase change material structure includes a plurality of two-dimensional material layers, and an intercalation material between the plurality of two-dimensional material layers.

In an embodiment of the inventive concept, a semiconductor device includes a substrate and an insulating layer on the substrate, a phase change material structure on the insulating layer, and a first source/drain electrode and a second source/drain electrode disposed on the phase change material structure and spaced apart from each other in a first direction, wherein the phase change material structure includes a plurality of two-dimensional material layers, and an intercalation material between the plurality of two-dimensional material layers, the intercalation material has first to third concentrations, and the intercalation material exhibits changes in behavior according to the first to third concentrations.

In an embodiment of the inventive concept, a method for manufacturing a semiconductor device includes preparing a substrate, forming an insulating layer on the substrate, forming a phase change material structure including a two-dimensional material layer on the insulating layer, and forming a first source/drain electrode and a second source/drain electrode on the phase change material structure, wherein the forming of a phase change material structure includes forming a two-dimensional material layer on the insulating layer, performing a first intercalation process on the two-dimensional material layer, and performing a second intercalation process after the first intercalation process, and the phase change material structure includes two-dimensional material layers and Ag ions between the two-dimensional material layers.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIGS. 1A and 1B are views showing semiconductor devices according to embodiments of the inventive concept;

FIGS. 2A and 2B are views corresponding to region M of FIG. 1B, and are enlarged views in an atomic scale according to an embodiment and another embodiment of the inventive concept;

FIGS. 3A to 3C are views corresponding to region N of FIG. 1B, and are enlarged views showing a crystal structure of a phase change material structure and the movement of an intercalation material according to a voltage applied to a source/drain electrode;

FIGS. 4, 5A, and 5B are views showing a crystal structure (i.e., crystal phase) of a two-dimensional material that may be applied to a semiconductor device according to an embodiment of the inventive concept;

FIGS. 6A to 7B are views schematically showing a portion of a semiconductor device according to an embodiment of the inventive concept, and are plan views showing the behavior of an intercalation material according to a concentration of the intercalation material;

FIGS. 8A to 8D are graphs showing the hysteresis curves of current versus applied voltage on a source/drain electrode upon varying exposure time to a lithium (Li)-containing solution; and

FIGS. 9A to 9C are graphs showing the hysteresis curves of current, retention time, and conductance versus applied voltage on a source/drain electrode according to an embodiment of the inventive concept.

### DETAILED DESCRIPTION

The phrase “in some embodiments” or “in an embodiment” often used herein may not all necessarily indicate the same embodiment.

The term “comprise” or “include” should be construed not as necessarily including various components or steps written in the present specification but as including the components or steps in part or further including additional components or steps.

Hereinafter, the expression “above” or “on” may denote not only direct contact from above/below/right/left, but also indirectly above/below/right/left without contact. Hereinafter, with reference to the accompanying drawings, a detailed description will be given by embodiments only for illustration.

The terms first, second, and the like may be used for describing various elements, but the elements are not limited by the terms. The terms are used to only distinguish one element from other elements.

Hereinafter, the present disclosure will be described in detail with reference to the accompanying drawings.

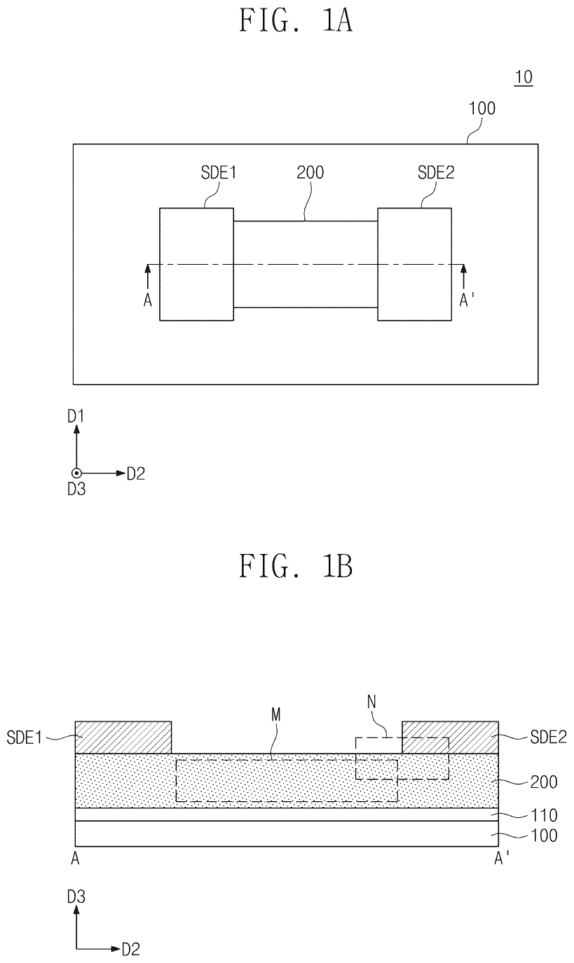

FIGS. 1A and 1B are views showing semiconductor devices according to embodiments of the inventive concept, where FIG. 1A is a plan view showing a semiconductor device 10 according to an embodiment and FIG. 1B is a cross-sectional view showing a semiconductor device 10 taken along line A-A′ of FIG. 1A. The semiconductor device 10 according to an embodiment of the inventive concept may be a horizontal memristor. . . . However, the embodiment of the inventive concept is not limited thereto.

As shown in FIGS. 1A and 1B, the semiconductor device 10 may include a substrate 100, an insulating layer 110 on the substrate, a phase change material structure 200, and first and second source/drain electrodes SDE1 and SDE2. The first and second source/drain electrodes SDE1 and SDE2 may be disposed to be spaced apart from each other in a second direction D2. A first direction D1 may be defined as a direction parallel to an upper surface of the substrate 100, and the second direction D2 may be defined as a direction parallel to an upper surface of the substrate 100 and crossing the first direction D1.

The substrate 100 may include at least one of a semiconductor substrate, for example, a silicon substrate, a germanium substrate, or a silicon-germanium substrate, or a combination thereof. The substrate 100 may be a multilayer substrate. For example, the substrate 100 may include a semiconductor substrate and an insulating substrate that are sequentially stacked. However, the embodiment of the inventive concept is not limited thereto.

Specifically, the substrate 100 may be a silicon substrate and the like, but is not limited thereto, and substrates of various materials may be used. In addition, a flexible substrate such as a plastic substrate may be used as the substrate 100. The insulating layer 110 may be provided on an upper surface of the substrate 100 for insulation between the substrate 100 and the phase change material structure 200. The insulating layer 110 may include, for example, silicon oxide, silicon nitride, and the like, but is not limited thereto. Meanwhile, when the substrate 100 includes an insulating material, the insulating layer 110 may not be provided on the upper surface of the substrate 100.

The phase change material structure 200 may be provided on the insulating layer 110. The phase change material structure 200 may cover at least a portion of the insulating layer 110. In a semiconductor device according to an embodiment of the inventive concept, the phase change material structure 200 may store information, resulting from changes in resistance due to electrical signals applied to the first and second source/drain electrodes SDE1 and SDE2 described below. The phase change material structure 200 may have a thickness on an atomic scale, and for example, the phase change material structure 200 may have a thickness of tens of nanometers or less. The thickness of the phase change material structure 200 may be defined as a distance in a third direction D3 perpendicular to the substrate 100. The third direction D3 may be defined as a direction crossing the first and second directions D1 and D2. Hereinafter, the phase change material structure 200 will be described in detail.

The first and second source/drain electrodes SDE1 and SDE2 may be provided on the phase change material structure 200. For example, the first and second source/drain electrodes SDE1 and SDE2 may have a plate shape on a plane view. However, the shape of the first and second source/drain electrodes SDE1 and SDE2 is not limited thereto and may have various shapes. The first and second source/drain electrodes SDE1 and SDE2 may include a conductive material. For example, the first and second source/drain electrodes SDE1 and SDE2 may include at least one of various conductive materials, such as Al, Au, Cu, Ir, Ru, Pt, Ti, TiN, Ta, TaN, and Cr.

Specifically, the first and second source/drain electrodes SDE1 and SDE2 may include an adhesive layer and a conductive metal pattern on the adhesive layer. The adhesive layer may be provided with a uniform thickness on the phase change material structure 200, and the conductive metal pattern may be provided on the adhesive layer. The adhesive layer may include, for example, Cr, Ti, or a combination thereof, and the conductive metal pattern may include, for example, Au, Al, Cu, or a combination thereof.

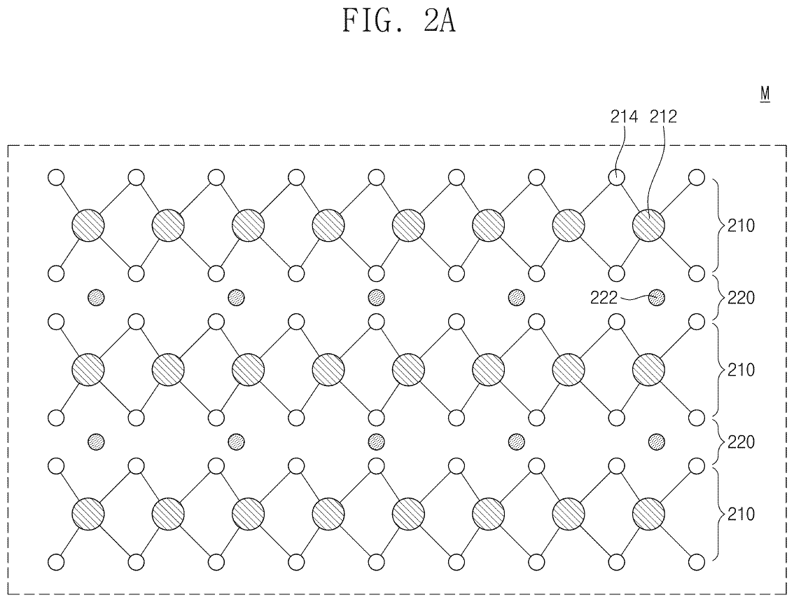

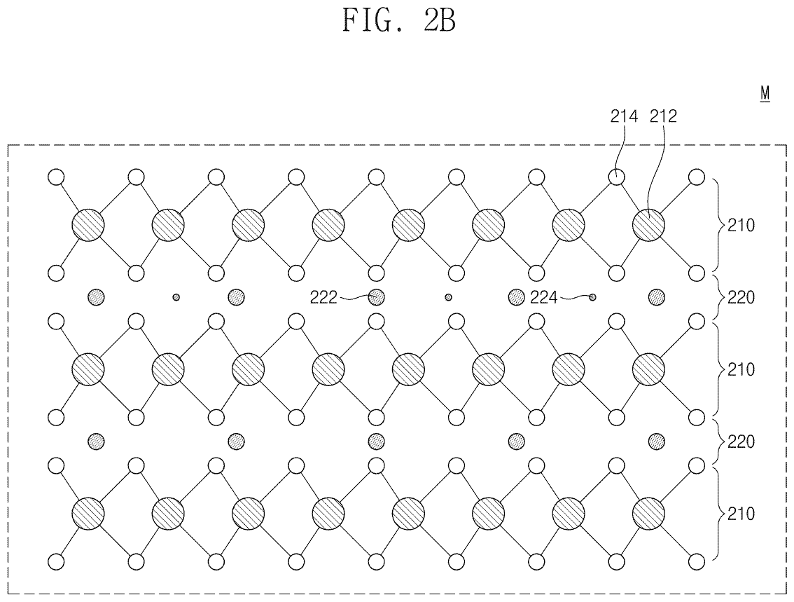

FIGS. 2A and 2B are views corresponding to region M of FIG. 1B, and are views enlarging region M of the phase change material structure 200. The region M may be a portion of the phase change material structure 200 whose crystal structure is changed by the first and second source/drain electrodes SDE1 and SDE2 described above. In FIG. 2A and FIG. 2B, some regions of the phase change material structure 200 are presented in an atomic scale showing the bonding state of atoms for convenience of description. In addition, FIG. 2A and FIG. 2B may correspond to different embodiments according to the inventive concept.

Referring to FIG. 2A, the phase change material structure 200 may include a plurality of two-dimensional material layers 210 including a two-dimensional material. The two-dimensional material may be a single-layer or half-layer solid in which atoms form a predetermined crystal structure. The two-dimensional material may have a layered structure. That is, the phase change material structure 200 may have a structure in which a plurality of single-layer structures are stacked.

The two-dimensional material constituting the plurality of two-dimensional material layers 210 may include a metal chalcogenide-based material having a two-dimensional crystal structure. The two-dimensional material constituting the two-dimensional material layers 210 may include a transition metal dichalcogenide (TMD) material. The TMD material may be indicated as MX2, where M is a transition metal 212 and X is a chalcogen element 214. The M may be Mo, W, Nb, V, Ta, Ti, Zr, Hf, Tc, or Re, and the X may be S, Se, or Te. As a specific example, the TMD material may be WSe₂, WTe₂, WS₂, MoSe₂, MoTe₂, MoS₂, ZrS₂, ZrSe₂, HfS₂, HfSe₂, NbSe₂, or ReSe₂. The TMD material may preferably include at least one of MoS₂, MoSe₂, MoTe₂, WS₂, WSe₂, or WTe₂. However, the TMD materials presented herein are only examples, and other TMD materials may be present. In addition, as another example, the two-dimensional material layers 210 may include other two-dimensional materials other than the TMD material.

The phase change material structure 200 may further include an intercalation material 220 inserted between the plurality of two-dimensional material layers 210. The intercalation material 220 may include a first metal material 222. The first metal material 222 may be silver (Ag) or nickel (Ni). For example, the intercalation material 220 may include Ag atoms or Ag ions, or Ni atoms or Ni ions. FIG. 2A shows a case in which a plurality of ions (e.g., Ag⁺ and Ni⁺) constituting the intercalation material 220 are regularly arranged, but this is for convenience of description, and the actual arrangement of ions may vary.

FIG. 2B is an enlarged view showing region M of FIG. 1B, and shows a different example from FIG. 2A. Referring to FIG. 2B, descriptions that overlap the above-described technical features will be skipped and differences will be described in detail.

Referring to FIG. 2B, the phase change material structure 200 may include a plurality of two-dimensional material layers 210 including a two-dimensional material and an intercalation material 220 inserted between the plurality of two-dimensional material layers 210. The intercalation material 220 may include a first metal material 222 and a second metal material 224. The first metal material 222 may be silver (Ag) or nickel (Ni), and the second metal material 224 may be lithium (Li) or potassium (K). For example, the intercalation material 220 may include Ag atoms or Ag ions, or Ni atoms or Ni ions. In addition, the intercalation material 220 may include Li atoms or Li ions, or K atoms or K ions. FIG. 2B shows a case in which a plurality of ions (e.g., Ag⁺ or Ni⁺, Li⁺ or K⁺) constituting the intercalation material 220 are regularly arranged, but this is for convenience of description, and the actual arrangement of ions may vary.

Specifically, the intercalation material 220 of FIG. 2B may be a mixture of Ag ions and Li ions. That is, the phase change material structure 200 may include an intercalation material 220 in which Ag ions and Li ions are mixed by widening a gap between the plurality of two-dimensional material layers 210 with Ag ions larger than Li ions. In this case, Li ions may move relatively easily between the two-dimensional material layers 210. Therefore, changes in reversible crystal structure of the two-dimensional material layers 210 may be more easily induced.

Referring back to FIGS. 2A and 2B, as an example, the phase change material structure 200 may have a hexagonal structure (hereinafter referred to as a 2H structure). As another example, the phase change material structure 200 may have at least one of a first monoclinic structure (hereinafter referred to as a 1T′ structure) or a second monoclinic structure (hereinafter referred to as a 1T structure). As another example, the phase change material structure 200 may all have a 2H structure, a 1T′ structure, and a 1T structure. However, the embodiment of the inventive concept is not limited thereto. The crystal structure of the phase change material structure 200 (e.g., the crystal structure in region N of FIG. 1B) may be reversibly changed by the second source/drain electrode SDE2 described below.

Referring to FIGS. 1A, 1B, and 2A, the semiconductor device 10 according to an embodiment of the inventive concept may have a relatively high resistance state (HRS) or a relatively low resistance state (LRS) by the phase change material structure 200. In this case, the high resistance state (HRS) may indicate an off state where the phase change material structure 200 has high resistance, resulting in poor current flow, and the low resistance state (LRS) may indicate on state where the phase change material structure 200 has low resistance, allowing for good current flow.

Specifically, when a portion of the phase change material structure 200 has a 1T′ structure or a 1T structure having high electrical conductivity (i.e., when the phase change material structure 200 has all of a 2H structure, a 1T′ structure, and a 1T structure), the semiconductor device 10 may have the low resistance state (LRS) due to the crystal structure of the phase change material structure 200. When a portion of the phase change material structure 200 has a 2H structure having low electrical conductivity, the semiconductor device 10 may have the high resistance state (HRS) due to the crystal structure of the phase change material structure 200.

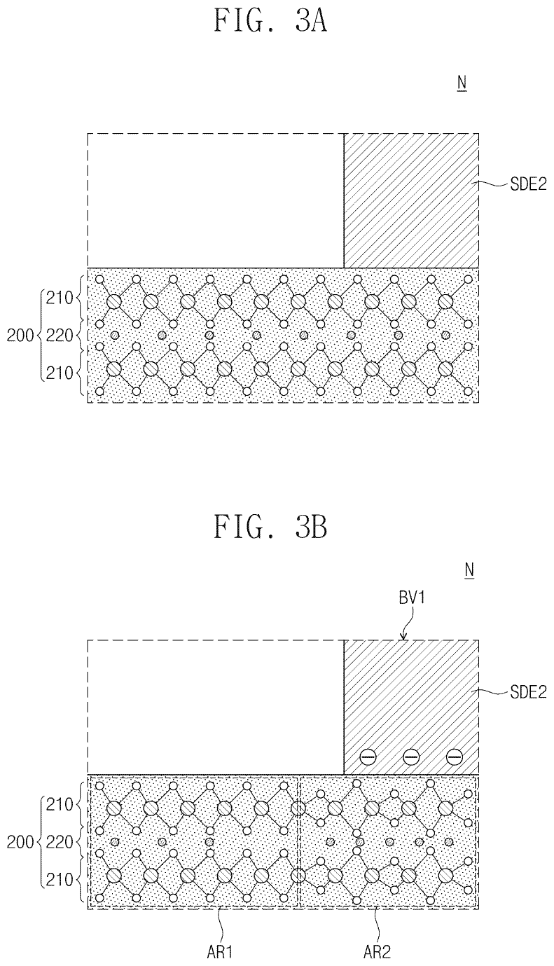

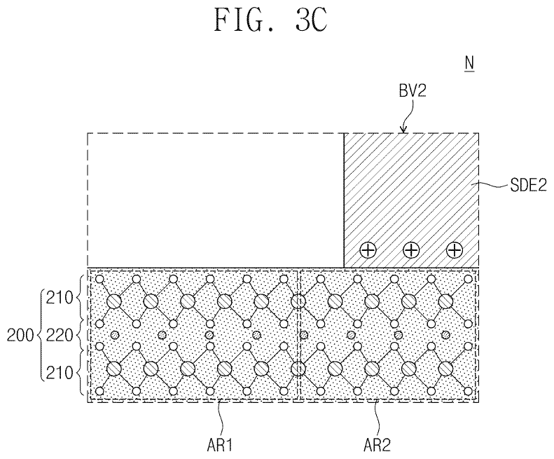

FIGS. 3A to 3C are views corresponding to region N of FIG. 1B, and are enlarged views showing a crystal structure of the phase change material structure 200 and the movement of the intercalation material 220 according to a voltage applied to the second source/drain electrode SDE2. FIG. 3A is an enlarged view show a case having no voltage applied to the second source/drain electrode SDE2. FIG. 3B is an enlarged view showing a case where a first voltage BV1 is applied to the second source/drain electrode SDE2, and FIG. 3C is an enlarged view showing a case where a second voltage BV2 is applied to the second source/drain electrode SDE2.

Referring to FIG. 3A, when there is no voltage applied to the second source/drain electrode SDE2, the crystal structure of the phase change material structure 200 may have a 2H structure. The intercalation material 220 between the two-dimensional material layers 210 may be uniformly distributed.

Referring to FIG. 3B, when the first voltage BV1 is applied to the second source/drain electrode SDE2, the phase change material structure 200 may include a first region AR1 having a 2H structure and a second region AR2 having a 1T′ structure. As another example, when the first voltage BV1 is applied to the second source/drain electrode SDE2, the phase change material structure 200 may include a first region AR1 having a 2H structure and a second region AR2 having a 1T structure. The first region AR1 may be defined as a region between the first and second source/drain electrodes SDE1 and SDE2, and the second region AR2 may be defined as a region adjacent to the second source/drain electrodes SDE2. Although not shown, a region adjacent to the first source/drain electrodes SDE1 (FIG. 1B) may be defined as a third region.

The intercalation material 220 between the two-dimensional material layers 210 may move toward the second source/drain electrode SDE2. When the first voltage BV1, which is a negative voltage, is applied to the second source/drain electrode SDE2, a metal ion, which is the intercalation material 220, may move toward the second source/drain electrode SDE2 due to an electric field formed around the second source/drain electrode SDE2. For example, the metal ion may be an Ag⁺ ion. That is, since the intercalation material 220 is not uniformly distributed, the concentration of the intercalation material 220 in the second region AR2 may be greater than the concentration of the intercalation material 220 in the first region AR1. The phase change material structure 200 has both a 2H structure and a 1T′ structure, or has all of a 2H structure, a 1T′ structure, and a 1T structure, and thus may have a low resistance state (LRS).

Referring to FIG. 3C, when a second voltage BV2 is applied to the second source/drain electrode SDE2, both the first region AR1 and the second region AR2 of the phase change material structure 200 may have a 2H structure. The intercalation material 220 between the two-dimensional material layers 210 may move away from the second source/drain electrode SDE2. When the second voltage BV2, which is a positive voltage, is applied to the second source/drain electrode SDE2, a metal ion, which is the intercalation material 220, may move away from the second source/drain electrode SDE2 due to an electric field formed around the second source/drain electrode SDE2. For example, the metal ion may be an Ag⁺ ion.

That is, as the metal ion, which is the intercalation material 220, moves away from the second source/drain electrode SDE2, the intercalation material 220 may be uniformly distributed again. That is, the concentration of the intercalation material 220 in the second region AR2 and the concentration of the intercalation material 220 in the first region AR1 may be the same. The phase change material structure 200 has a 2H structure, and thus may have a high resistance state (HRS). Referring back to FIGS. 3A to 3C, the crystal structure of the phase change material structure 200 may reversibly change according to voltage applied to the second source/drain electrode SDE2.

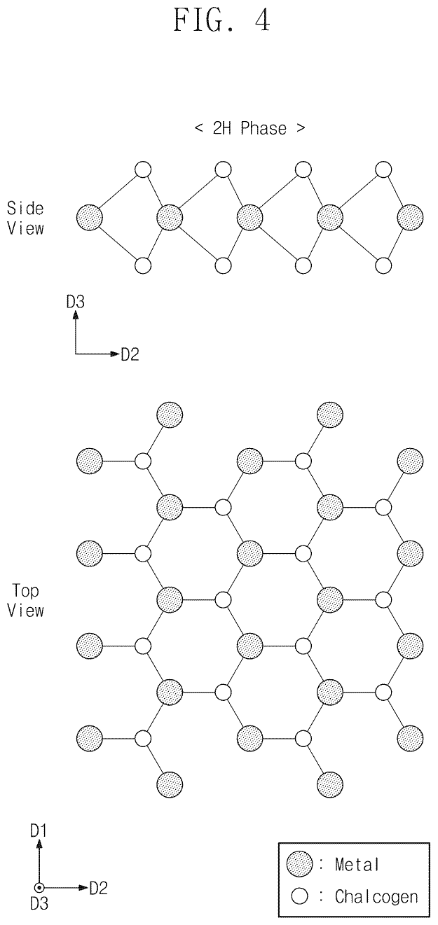

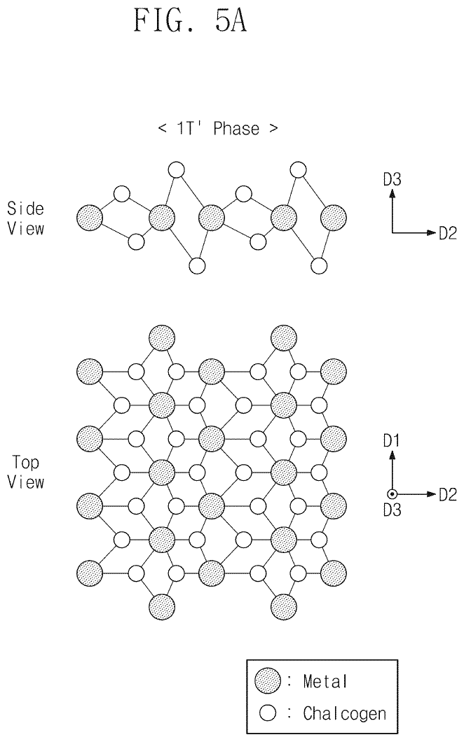

FIGS. 4 and 5A to 5B are views showing a crystal structure (i.e., crystal phase) of a two-dimensional material that may be applied to a semiconductor device according to an embodiment of the inventive concept. The hexagonal structure (hereinafter referred to as 2H structure), the first monoclinic structure (hereinafter referred to as 1T′ structure), and the second monoclinic structure (hereinafter referred to as 1T structure) of the phase change material structure 200 described above will be described in detail with reference to FIGS. 4 and 5.

FIG. 4 is a view showing a first crystal structure (i.e., a first crystal phase) of a two-dimensional material of a two-dimensional material layer 210. FIG. 5A is a view showing a second crystal structure (i.e., a second crystal phase) of a two-dimensional material of a two-dimensional material layer 210, and FIG. 5B is a view showing a third crystal structure (i.e., a third crystal phase) of a two-dimensional material of a two-dimensional material layer 210. A two-dimensional material in the present embodiment may be MX₂, where M is a metal element and X is a chalcogen element. The two-dimensional material may be a TMD material, and preferably may be at least one of MoS₂, MoSe₂, MoTe₂, WS₂, WSe₂, or WTe2. FIG. 4 includes a structure viewed from a side (i.e., a side view) and a structure viewed from above (i.e., a top view). This also applies to FIGS. 5A and 5B.

Referring to FIG. 4, the first crystal structure that a two-dimensional material MX₂ may have may be a 2H structure. This 2H structure may exhibit semiconductor properties. Referring to FIG. 5A, the second crystal structure that a two-dimensional material MX₂ may have may be a 1T′ structure. Referring to FIG. 5B, the third crystal structure that a two-dimensional material MX₂ may have may be a 1T structure. These 1T′ and 1T structures may exhibit metallic or semi-metallic properties. That is, from a planar perspective, the 2H structure takes the form of regularly repeating hexagons of the same size and thus may exhibit semiconductor properties. From a planar perspective, the 1T′ structure takes the form of irregularly repeating squares of different sizes, and the 1T structure takes the form of regularly repeating squares of the same size, and thus both may exhibit metallic or semi-metallic properties.

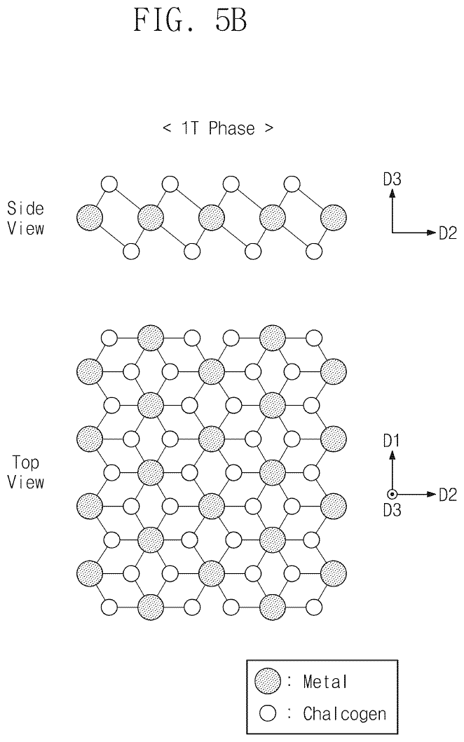

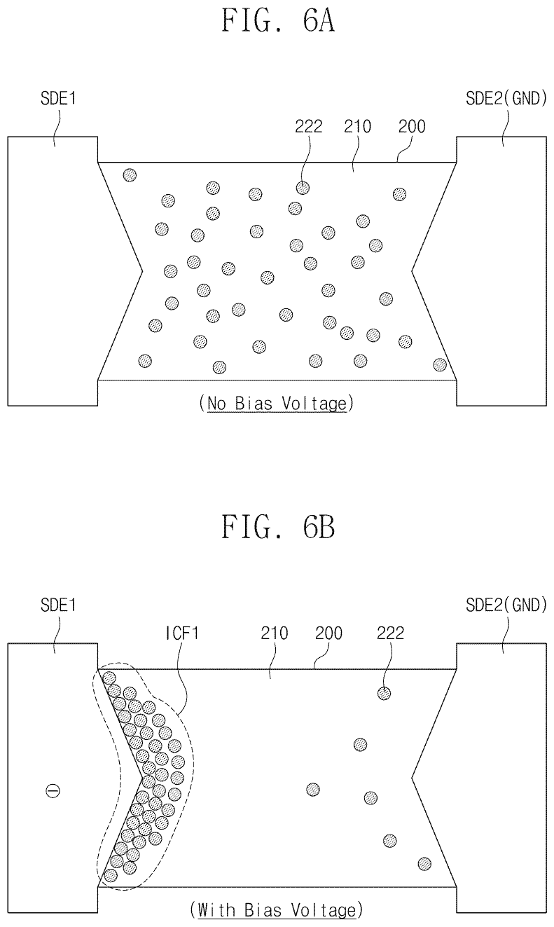

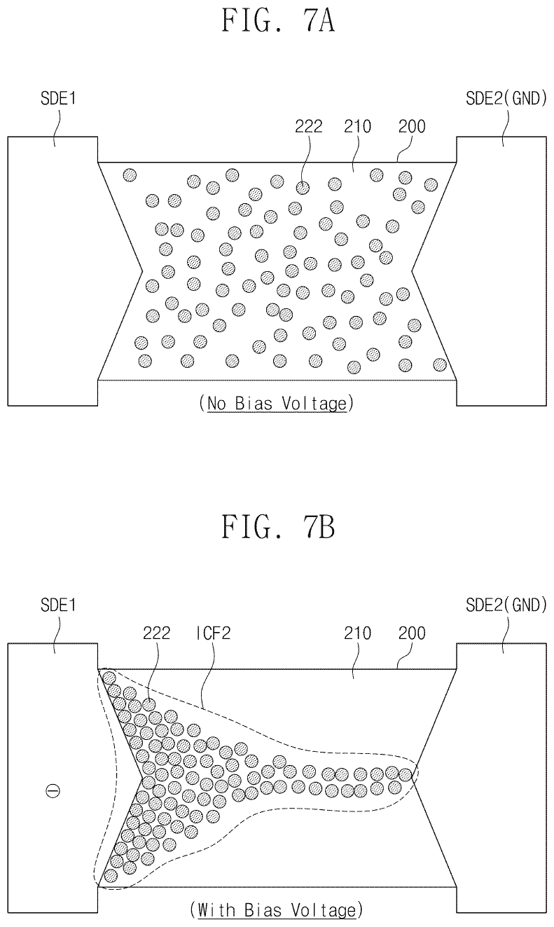

FIGS. 6A to 7B are views schematically showing a portion of a semiconductor device according to an embodiment of the inventive concept, and are plan views showing the behavior of an intercalation material according to concentration of the intercalation material. For convenience of description, FIGS. 6A to 7B are illustrated in an atomic scale showing a state of the intercalation material 200 in the phase change material structure 200. That is, FIGS. 6A to 7B are conceptual views showing the behavior of the intercalation material 200 between the first and second source/drain electrodes SDE1 and SDE2. Hereinafter, a detailed description of how a memristor according to an embodiment works will be provided based on the concentration of an inserted intercalation material with reference to FIGS. 1A, 1B, 2, and 6A to 7B.

The phase change material structure 200 may include the two-dimensional material layers 210 including a two-dimensional material and an intercalation material 220 inserted between the two-dimensional material layers 210. The two-dimensional material constituting the two-dimensional material layers 210 may include a TMD material, and the TMD material may be indicated as MX₂ (where M is a transition metal 212 and X is a chalcogen element 214). The intercalation material 220 may include a first metal material 222, and the first metal material 222 may be indicated as Y (where Y is a metal ion).

The phase change material structure 220 may be indicated as MX₂-Y, and for example, MX₂-Y may be at least one of MoS₂—Ag, MoSe₂—Ag, MoTe₂—Ag, WS₂—Ag, WSe₂—Ag, or WTe₂—Ag. For example, the phase change material structure 200 may preferably be MoTe₂—Ag. However, the phase change material structure 200 including MoTe₂—Ag presented herein is an example, and the embodiment of the inventive concept is not limited thereto. The concentration of Ag in the phase change material structure 200 may involve a first concentration, a second concentration, or a third concentration. For example, the first concentration may be in a range of about 10 at % to about 15 at %, the second concentration may be in a range of about 16 at % to about 20 at %, and the third concentration may be in a range of about 21 at % to about 25 at %.

When the concentration of Ag in the phase change material structure 200 is the first concentration, the semiconductor device 10 according to an embodiment of the inventive concept may be a memristor having a first operation mode. The first operation mode may indicate a mode where Ag⁺ ions are inserted at a relatively low concentration into the van der Waals gap, which is a gap between the two-dimensional material layers 210, thereby operating as a semiconductor device doped with Ag⁺ ions. That is, a change in current may be induced by Ag⁺ ions which are dopants in the phase change material structure 200.

Referring to FIGS. 6A and 6B, when the concentration of Ag in the phase change material structure 200 is the second concentration, the semiconductor device 10 according to an embodiment of the inventive concept may be a memristor having a second operation mode. The second operation mode may indicate a mode where a phase transition takes place around electrodes according to electrical signals applied to the first and second source/drain electrodes SDE1 and SDE2, thereby changing resistance. That is, an electric field formed by voltage applied to the first and second source/drain electrodes SDE1 and SDE2 causes Ag⁺ ions to move around electrodes, resulting in a phase transition in the phase change material structure 200.

Specifically, when there is no voltage applied to the first and second source/drain electrodes SDE1 and SDE2, the first metal material 222 may be relatively uniformly distributed between the two-dimensional material layers 210. Referring to FIGS. 3A, 5, and 6A, the phase change material structure 200 may have a 2H structure.

That is, the phase change material structure 200 may have the high resistance state (HRS) described above due to the van der Waals gap or Schottky barrier present at an interface between the first and second source/drain electrodes SDE1 and SDE2 and the two-dimensional material layer 210.

When a negative voltage is applied to the first source/drain electrode SDE1 and a ground voltage GND is applied to the second source/drain electrode SDE2, an electric field may be formed between the first and second source/drain electrodes SDE1 and SDE2. Accordingly, the first metal material 222, which is a positive ion, may move around the first source/drain electrode SDE1 and have a first cluster form ICF1. Most of the first metal material 222 may form the first cluster form ICF1, and the remaining portion of the first metal material 222 may reside around the second source/drain electrode SDE2.

Referring to FIGS. 3B, 5A, 5B, and 6B, the phase change material structure 200 around the first source/drain electrode SDE1 may have a 1T′ structure or a 1T structure due to the first cluster form ICF1. Due to the 1T′ structure or the 1T structure, the Schottky barrier between the source/drain electrode SDE1 and the two-dimensional material layer 210 may be reduced, resulting in the low resistance state (LRS) described above.

Referring to FIGS. 7A and 7B, when the concentration of Ag in the phase change material structure 200 is the third concentration, the semiconductor device 10 according to an embodiment of the inventive concept may be a memristor having a third operation mode. The third operation mode may indicate a mode where a phase transition takes place around electrodes according to electrical signals applied to the first and second source/drain electrodes SDE1 and SDE2, thereby changing resistance. That is, an electric field formed by voltage applied to the first and second source/drain electrodes SDE1 and SDE2 causes Ag⁺ ions to move around electrodes, resulting in a phase transition in the phase change material structure 200. Since the third concentration is greater than the second concentration, the cluster shape of the first metal material 222 may change.

Specifically, when there is no voltage applied to the first and second source/drain electrodes SDE1 and SDE2, the first metal material 222 may be relatively uniformly distributed between the two-dimensional material layers 210. Referring to FIGS. 3A, 5, and 7A, the phase change material structure 200 may have a 2H structure. That is, the phase change material structure 200 may have the high resistance state (HRS) described above due to the van der Waals gap or Schottky barrier present at an interface between the first and second source/drain electrodes SDE1 and SDE2 and the two-dimensional material layer 210.

When a negative voltage is applied to the first source/drain electrode SDE1 and a ground voltage GND is applied to the second source/drain electrode SDE2, an electric field may be formed between the first and second source/drain electrodes SDE1 and SDE2. Accordingly, the first metal material 222, which is a positive ion, may move around the first source/drain electrode SDE1 and have a second cluster form ICF2. Specifically, the concentration of Ag as the third concentration is relatively high, the first metal material 222 may connected the first and second source/drain electrodes SDE1 and SDE2 along the formed electric field.

The second cluster form ICF2 may be an atomic-scale conductive filament connecting the first and second source/drain electrodes SDE1 and SDE2 due to the Ag⁺ ions included in a high concentration. For example, the second cluster form ICF2 may be an Ag⁺ ion filament. The second cluster form ICF2 may be formed along defective grain boundaries of the phase change material structure 200. This may be because, based on the first-principle density functional theory, the voltage for diffusing the conductive filament through the defective grain boundaries is smaller than the voltage for diffusing the conductive filament through crystalline part of the two-dimensional material layer 210.

Referring to FIGS. 3B, 5A, 5B, and 7B, the phase change material structure 200 between the first and second source/drain electrodes SDE1 and SDE2 may have a 1T′ structure or a 1T structure due to the second cluster form ICF2. Due to the 1T′ structure or the 1T structure, the Schottky barrier between the first and second source/drain electrodes SDE1 and SDE2 and the two-dimensional material layer 210 may be reduced, resulting in the low resistance state (LRS) described above.

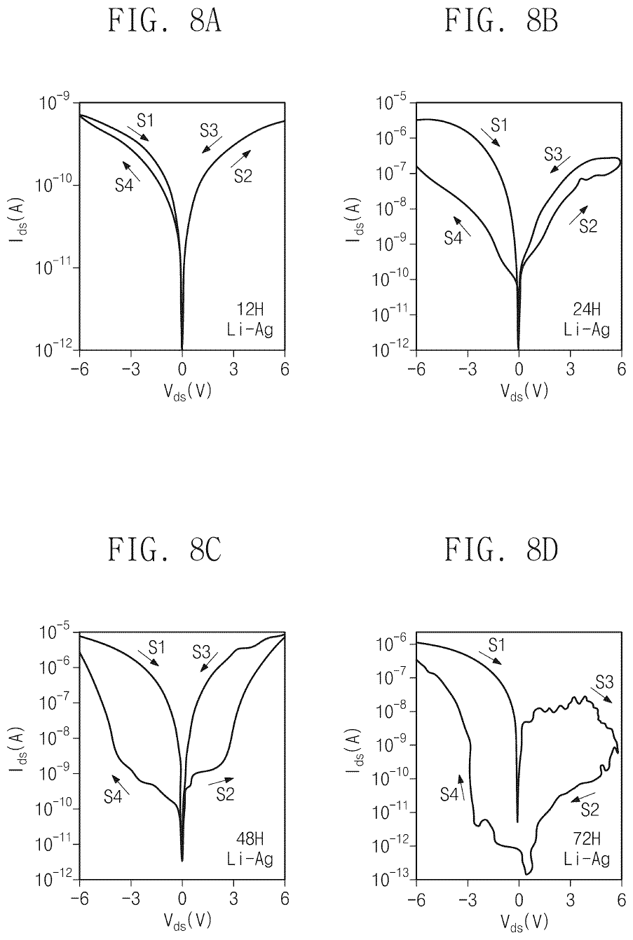

FIGS. 8A to 8D are graphs showing the hysteresis curves of current versus applied voltage on a source/drain electrode upon varying exposure time to a lithium (Li)-containing solution. Referring to FIGS. 8A to 8D, when a voltage (bias voltage) is applied to the second source/drain electrode SDE2, the crystal structure in the phase change material structure 200 may be changed accordingly. Voltage values may be controlled to repeatedly increase and decrease in a certain range, and in this specification, a minimum repeated cycle of the voltage value change is defined as one cycle. For example, as shown in FIGS. 8A to 8D, voltage values may repeatedly increase and decrease along a first section S1, a second section S2, a third section S3, and a fourth section S4, and the first to fourth sections S1, S2, S3, and S4 may constitute one cycle of voltage value change.

Referring to FIGS. 8A to 8D, it is determined that hysteresis curves of current between the first and second source/drain electrodes SDE1 and SDE2 and the phase change material structure 200 change over time that the TMD material is exposed to an n-butyl lithium solution in the manufacture of the semiconductor device 10 (e.g., a memristor) including a TMD material. In this case, the measured current value is a current value generated by applying voltage to the second source/drain electrode SDE2.

One cycle of the voltage applied to the second source/drain electrode SDE2 consists of the first to fourth sections S1, S2, S3, and S4. The first section S1 is a section in which an absolute value of the applied voltage increases from a negative voltage to 0 V. The second section S2 is a section in which an absolute value of the applied voltage increases from 0 V to a positive voltage. The first and second sections S1 and S2 are sections in which the absolute values of the applied voltage increase, but the directions of electric fields formed thereby may be opposite to each other. The third section S3 is a section in which an absolute value of the applied voltage decreases from a positive voltage to 0 V. The fourth section S4 is a section in which an absolute value of the applied voltage decreases from 0 V to a negative voltage. The third and fourth sections S3 and S4 are sections in which the absolute values of the applied voltage decrease, but the directions of electric fields formed thereby may be opposite to each other.

FIG. 8A is a graph showing a hysteresis curve of current when voltage is applied to a semiconductor device 10 (e.g., a memristor) including a TMD material exposed to an n-butyl lithium solution (10 mL, concentration: 1.6 M) for 12 hours.

Referring to FIG. 8A, the current decreases in the first and third sections S1 and S3 and increases in the second and fourth sections S2 and S4. The current values according to the same voltage in the first and fourth sections S1 and S4 are shown to be similar to each other, and the current values according to the same voltage in the second and third sections S2 and S3 are shown to be similar to each other. This is because when the TMD material is exposed to an n-butyl lithium solution (10 mL, concentration: 1.6 M) for 12 hours (that is, when the concentration of Ag inserted into the phase change material structure 200 is the first concentration), the relative low doping concentration of Ag prevents phase change of the phase change material structure 200 around source/drain electrodes. That is, since no phase change takes place, there may be no change in electrical conductivity accordingly.

FIG. 8B is a graph showing a hysteresis curve of current when voltage is applied to a semiconductor device 10 (e.g., a memristor) including a TMD material exposed to an n-butyl lithium solution (10 mL, concentration: 1.6 M) for 24 hours.

Referring to FIG. 8B, the current decreases in the first and third sections S1 and S3 and increases in the second and fourth sections S2 and S4. The current values according to the same voltage in the first and fourth sections S1 and S4 are shown to be different from each other, and the current values according to the same voltage in the second and third sections S2 and S3 are shown to be different from each other. This is because when the TMD material is exposed to an n-butyl lithium solution (10 mL, concentration: 1.6 M) for 24 hours (that is, when the concentration of Ag inserted into the phase change material structure 200 is the second concentration), due to the inserted Ag⁺ ions, the crystal structure of the phase change material structure 200 changes from a 2H structure to a 1T′ structure or from a 2H structure to a 1T structure around source/drain electrodes. That is, phase change of the phase change material structure 200 takes place around source/drain electrodes, and accordingly electrical conductivity may increase.

Specifically, in the first and fourth sections S1 and S4 where a negative voltage is applied to the second source/drain electrode SDE2 to form an electric field, Ag⁺ ions may move to the second source/drain electrode SDE2 to change the crystal structure of the phase change material structure 200 from a 2H structure to a 1T′ structure or from a 2H structure to a 1T structure. In this case, Ag⁺ ions may form the first cluster form ICF1 (FIG. 6B) around the second source/drain electrode SDE2.

Since the influence of electric fields formed by a negative voltage weakens in the first section S1, the first section S1 may be a section in which Ag⁺ ions move to be uniformly distributed in the phase change material structure 200 in the first cluster form ICF1 (FIG. 6B). Since the influence of electric fields formed by a negative voltage is strengthened in the fourth section S4, the fourth section S4 may be a section in which Ag⁺ ions uniformly distributed in the phase change material structure 200 move to form the first cluster form ICF1 (FIG. 6B) again. That is, the first cluster form ICF1 (FIG. 6B) of the first section S1 may have greater density of Ag⁺ ions than the first cluster form ICF1 (FIG. 6B) of the fourth section S4. That is, even when the same voltage is provided due to the 1T′ structure or the 1T structure of the changed phase change material structure 200, the current value may be observed higher in the first section S1 than in the fourth section S4.

On the contrary, in the second and third sections S2 and S3 where a positive voltage is applied to the second source/drain electrode SDE2 to form an electric field, Ag⁺ ions may move away from the second source/drain electrode SDE2 to change the crystal structure of the phase change material structure 200 from a 1T′ structure to a 2H structure or from a 1T structure to a 2H structure again.

Since the influence of electric fields formed by a positive voltage is strengthened in the second section S2, the second section S2 may be a section in which Ag⁺ ions in the phase change material structure 200 move to be uniformly distributed. Since the influence of electric fields formed by a positive voltage weakens in the third section S3, the third section S3 may be a section in which Ag⁺ ions uniformly distributed in the phase change material structure 200 move again toward the second source/drain electrode SDE2. That is, the uniformity of Ag⁺ ions in the phase change material structure 200 in the second section S2 may be greater than the uniformity of Ag⁺ ions in the phase change material structure 200 in the third section S3. That is, even when the same voltage is provided due to the 2H structure of the changed phase change material structure 200, the current value may be observed lower in the second section S2 than in the third section S3.

FIG. 8C is a graph showing a hysteresis curve of current when voltage is applied to a semiconductor device 10 (e.g., a memristor) including a TMD material exposed to an n-butyl lithium solution (10 mL, concentration: 1.6 M) for 48 hours. The graph of the current hysteresis curve according to FIG. 8C shows a case of having an optimal concentration of the second concentration of Ag inserted into the phase change material structure 200.

Referring to FIG. 8C, the current decreases in the first and third sections S1 and S3 and increases in the second and fourth sections S2 and S4. The current values according to the same voltage in the first and fourth sections S1 and S4 are shown to be different from each other, and the current values according to the same voltage in the second and third sections S2 and S3 are shown to be different from each other. This is because when the TMD material is exposed to an n-butyl lithium solution (10 mL, concentration: 1.6 M) for 48 hours (that is, when the concentration of Ag inserted into the phase change material structure 200 is the second concentration), due to the inserted Ag⁺ ions, the crystal structure of the phase change material structure 200 changes from a 2H structure to a 1T′ structure or from a 2H structure to a 1T structure around source/drain electrodes. That is, phase change of the phase change material structure 200 takes place around source/drain electrodes, and accordingly electrical conductivity may increase.

FIG. 8D is a graph showing a hysteresis curve of current when voltage is applied to a semiconductor device 10 (e.g., a memristor) including a TMD material exposed to an n-butyl lithium solution (10 mL, concentration: 1.6 M) for 72 hours.

Referring to FIG. 8D, the current decreases in the first and third sections S1 and S3, the current increases and then decreases in the second section S2, and the current increases in the fourth section S4. The current values according to the same voltage in the first and fourth sections S1 and S4 are shown to be different from each other, and the current values according to the same voltage in the second and third sections S2 and S3 are shown to be different from each other. This is because when the TMD material is exposed to an n-butyl lithium solution (10 mL, concentration: 1.6 M) for 72 hours (that is, when the concentration of Ag inserted into the phase change material structure 200 is the third concentration), due to the inserted Ag⁺ ions, the crystal structure of the phase change material structure 200 changes from a 2H structure to a 1T′ structure or from a 2H structure to a 1T structure around source/drain electrodes. Furthermore, the inserted Ag⁺ ions may form a conductive filament connecting the first and second source/drain electrodes SDE1 and SDE2. That is, phase change of the phase change material structure 200 takes place around and between source/drain electrodes, and accordingly electrical conductivity may increase.

Specifically, in the first and fourth sections S1 and S4 where a negative voltage is applied to the second source/drain electrode SDE2 to form an electric field, Ag⁺ ions may move to the second source/drain electrode SDE2 to change the crystal structure of the phase change material structure 200 from a 2H structure to a 1T′ structure or from a 2H structure to a 1T structure. In this case, Ag⁺ ions may form the second cluster form ICF2 (FIG. 7B) between the first and second source/drain electrodes SDE1 and SDE2.

Since the influence of electric fields formed by a negative voltage weakens in the first section S1, the first section S1 may be a section in which the second cluster form ICF2 (FIG. 7B) of Ag⁺ ions weakens. Since the influence of electric fields formed by a negative voltage is strengthened in the fourth section S4, the fourth section S4 may be a section in which the second cluster form ICF2 (FIG. 7B) of Ag⁺ ions is strengthened. That is, the second cluster form ICF2 (FIG. 7B) of the first section S1 may have greater density of Ag⁺ ions than the second cluster form ICF2 (FIG. 7B) of the fourth section S4. That is, even when the same voltage is provided due to the 1T′ structure or the 1T structure of the changed phase change material structure 200, the current value may be observed higher in the first section S1 than in the fourth section S4. In this case, the phase change material structure 200 includes a conductive filament composed of the 1T′ structure or the 1T structure, and Ag⁺ ions, and even when this causes the voltage value reduced to 0 V, the resulting current value may not be 0.

On the contrary, since the influence of electric fields formed by a positive voltage is strengthened in the second section S2, the second section S1 may be a section in which the second cluster form ICF2 (FIG. 7B) of Ag⁺ ions weakens. In a switching point of the second and third sections S2 and S3 where a positive voltage is applied to the second source/drain electrode SDE2 to form an electric field, due to the weak presence or absence of the second cluster form ICF2 (FIG. 7B) of Ag⁺ ions, the crystal structure of the phase change material structure 200 may change from a 1T′ structure to a 2H structure or from a 1T structure to a 2H structure again. Since the influence of electric fields formed by a positive voltage weakens in the third section S3, the third section S3 may be a section in which the second cluster form ICF2 (FIG. 7B) of Ag⁺ ions is strengthened. That is, the second cluster form ICF2 (FIG. 7B) of the second section S2 may have greater density of Ag⁺ ions than the second cluster form ICF2 (FIG. 7B) of the third section S3. That is, even when the same voltage is provided due to the second cluster form ICF2 (FIG. 7B) of Ag⁺ ions between the first and second source/drain electrodes SDE1 and SDE2, the current value may be higher in the second section S2 than in the third section S3.

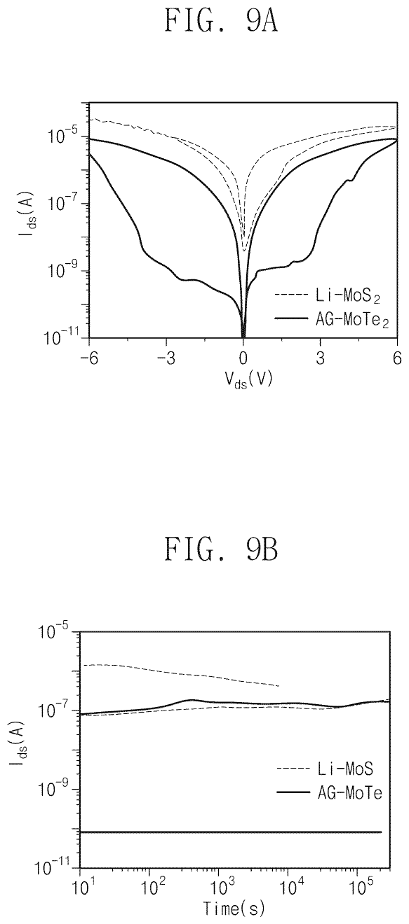

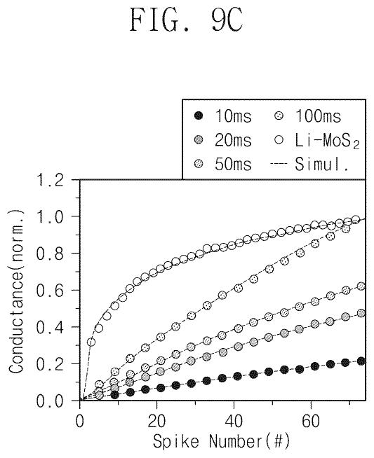

FIGS. 9A to 9C are graphs showing the hysteresis curves of current, retention time, and conductance versus applied voltage on a source/drain electrode according to an embodiment of the inventive concept. FIGS. 9A to 9C are graphs comparing performance of memristor or synaptic elements including the phase change material structure 220 that is either MoS₂−Li or MoTe₂−Ag.

Referring to FIGS. 9B and 9D, by inserting Ag⁺ ions, instead of typical alkali metals (e.g., Li⁺ ions), into the phase change material structure 200, a semiconductor device 10 capable of achieving high mobility and easily forming clusters within the van der Waals gap even under low electric fields may be provided. For example, the semiconductor device 10 may be a phase transition memristor based on a TMD material.

In addition, applying MoTe₂, exhibiting stability that is not easily affected by the ambient condition of Ag ions and low off-state current characteristics, as the two-dimensional material layer 210 of the phase change material structure 200 enables the semiconductor device 10 to achieve an on/off ratio of about 104 to about 106. In terms of reliability of the semiconductor device 10, retention time may be 20,000 seconds (sec) or less. Thus, according to an embodiment of the inventive concept, a semiconductor device (e.g., a memristor) having improved electrical characteristics and reliability may be provided.

Referring to FIG. 9C, by inserting Ag⁺ ions, instead of typical alkali metals (e.g., Li⁺ ions), into the phase change material structure 200, linearity may be improved (e.g., β=0.5) in the long-term potentiation (LTP) measurement. That is, the semiconductor device 10 including MoTe₂-Ag has bipolar resistive switching characteristics and analog resistive switching characteristics, and thus may serve as an artificial synapse. For example, a phase transition memristor including MoTe₂-Ag may perform synapse-like learning behaviors such as spike-timing dependent plasticity (STDP). STDP having low switching voltage enables low-power neuromorphic computing. In addition, the low switching voltage is close to biological potentials, and thus direct interfacing with mammalian neural networks may also be achievable. Therefore, the memristor according to an embodiment may be configured as a component of a neuromorphic device. Thus, according to an embodiment of the inventive concept, a novel neuromorphic synaptic element having synaptic plasticity may be provided.

Referring back to FIGS. 1A, 1B, and 2A, a method for manufacturing a semiconductor device including a two-dimensional material layer 210 and an intercalation material 220 according to an embodiment of the inventive concept may be provided.

The method for manufacturing a semiconductor device according to an embodiment of the inventive concept may include preparing a substrate 100, forming an insulating layer 110 on the substrate 100, forming a phase change material structure 200 including a two-dimensional material layer 210 on the insulating layer 110, and forming first and second source/drain electrodes SDE1 and SDE2 on the phase change material structure 200. For example, the substrate 100 may be doped silicon, and the insulating layer 110 may be silicon oxide. However, the materials of the substrate 100 and the insulating layer 110 may vary.

The forming of the phase change material structure 200 including two-dimensional material layers 210 on the insulating layer 110 may include forming two-dimensional material layers 210, performing a first intercalation process, and performing a second intercalation process.

The forming of the two-dimensional material layers 210 may provide two-dimensional material layers 210 including a two-dimensional material (2D material) on the insulating layer 110. The two-dimensional material of the two-dimensional material layers 210 may have a layered structure. The two-dimensional material layers 210 may include a single-layer structure having a two-dimensional crystal structure, and may have a structure in which a plurality of single-layer structures are stacked. The two-dimensional material may include a metal chalcogenide-based material, for example, a transition metal dichalcogenide (TMD) material. The TMD material may be indicated as MX2, where M is a transition metal 212 and X is a chalcogen element 214. The M may be Mo, W, Nb, V, Ta, Ti, Zr, Hf, Tc, or Re, and the X may be S, Se, or Te. As a specific example, the TMD material may be WSe₂, WTe₂, WS₂, MoSe₂, MoTe₂, MoS₂, ZrS₂, ZrSe₂, HfS₂, HfSe₂, NbSe₂, or ReSe₂. The TMD material may preferably include at least one of MoS₂, MoSe₂, MoTe₂, WS₂, WSe₂, or WTe₂. In this process, the two-dimensional material of the two-dimensional material layers 210 may entirely have the same (or substantially the same) crystal structure. For example, the two-dimensional material may entirely have a 2H structure (2H phase). The two-dimensional material layers 210 may be formed on the insulating layer 110 through a dry transfer method, or may be formed on the insulating layer 110 through a growth method or a deposition method.

The performing of the first intercalation process may include treating an element unit formed up to the two-dimensional material layers 210, using a first intercalation solution, and washing the resulting product after the first intercalation solution treatment. The first intercalation solution may include a first intercalation material, and the first intercalation material may include lithium (Li), potassium (K), or the like. For example, the first intercalation solution may include at least one selected from the group consisting of n-butyl lithium, tert-butyl lithium (t-Bu—Li), methyl lithium (Me—Li), and a potassium hexafluorophosphate solution.

Specifically, the first intercalation process may involve exposing the element unit to the first intercalation solution (e.g., a solution in which n-butyl lithium is diluted in hexane, 10 mL, concentration: 1.6 M) for a predetermined time in an Ar (99.999%) environment in a sealed flask. The predetermined time may be, for example, 12 hours, 24 hours, 48 hours, or 72 hours. The washing after the first intercalation solution treatment may be washing using hexane and isopropyl alcohol to remove Li and byproducts.

The performing of the second intercalation process may include treating the element unit into which Li ions are inserted in the two-dimensional material layers 210, using a second intercalation solution, and washing the resulting product after the second intercalation solution treatment. The second intercalation solution may include a second intercalation material, and the second intercalation material may include silver (Ag), nickel (Ni), or the like. For example, the second intercalation solution may be a solution in which 100 mL of N-methyl-2-pyrrolidone and 53.1 mg of AgNO₃ are mixed. Specifically, the second intercalation process may involve making the element unit react with the second intercalation solution for 4 hours. Washing after the second intercalation solution treatment may be washing using ethanol to remove impurities remaining on a surface of the element unit. After the second intercalation process is performed, Ag ions may be inserted into the van der Waasl gap of the element unit.

The first and second source/drain electrodes SDE1 and SDE2 may be formed on the two-dimensional material layers 210. The first and second source/drain electrodes SDE1 and SDE2 may be formed of metals or metal compounds. As another example, the first and second source/drain electrodes SDE1 and SDE2 may be formed of two-dimensional conductors such as graphene. The first and second source/drain electrodes SDE1 and SDE2 may be formed by performing a process of electron-beam lithography or photolithography. In this process, a specific physical vapor deposition (PVD) method may be used in the deposition of metals or metal compounds. For example, the metals or metal compounds may be subjected to deposition using an e-beam evaporation method or a thermal evaporation method.

By inserting Ag ions into the van der Waals gap of TMD materials, metal (1T′)-semiconductor (2H) phase transition may be further facilitated and the inserted Ag may become stable in ambient conditions. Accordingly, a semiconductor device (e.g., a memristor) including a TMD material into which Ag ions are inserted, may have improved electrical characteristics and reliability. The semiconductor device including a TMD material into which Ag ions are inserted exhibits high linearity in long-term potentiation (LTP) measurements and thus this memristor may be provided as a next-generation synaptic element. That is, this memristor may be applied as a novel neuromorphic synaptic element.

Although the embodiments of the inventive concept have been described above with reference to the accompanying drawings, those skilled in the art to which the inventive concept pertains may implement the inventive concept in other specific forms without changing the technical idea or essential features thereof. Therefore, it should be understood that the embodiments described above are exemplary in all respects and not restrictive.

What is claimed is:

1. A semiconductor device comprising:
a substrate;
an insulating layer on the substrate;
a phase change material structure on the insulating layer; and
a first source/drain electrode and a second source/drain electrode disposed on the phase change material structure and spaced apart from each other in a first direction,
wherein the phase change material structure includes:
a plurality of two-dimensional material layers; and
an intercalation material between the plurality of two-dimensional material layers.

2. The semiconductor device of claim 1, wherein the phase change material structure comprises:
a first region positioned between the first source/drain electrode and the second source/drain electrode;
a second region adjacent to the second source/drain electrode; and
a third region adjacent to the first source/drain electrode,
wherein the first to third regions have a hexagonal structure (2H structure).

3. The semiconductor device of claim 2, wherein as a first voltage is applied to the second source/drain electrode, the second region changes from the hexagonal structure to a first monoclinic structure (1T′ structure) or a second monoclinic structure (1T structure).

4. The semiconductor device of claim 3, wherein as a second voltage is applied to the second source/drain electrode, the second region changes from the first monoclinic structure to the hexagonal structure or from the second monoclinic structure to the hexagonal structure.

5. The semiconductor device of claim 4, wherein the phase change material structure has a crystal structure that changes reversibly according to voltages applied or removed.

6. The semiconductor device of claim 1, wherein the plurality of two-dimensional material layers each comprise a transition metal dichalcogenide (TMD).

7. The semiconductor device of claim 6, wherein the TMD comprises at least one of MoS₂, MoSe₂, MoTe₂, WS₂, WSe₂, or WTe₂.

8. The semiconductor device of claim 1, wherein the intercalation material comprises at least one of silver (Ag) or nickel (Ni).

9. The semiconductor device of claim 1, wherein the intercalation material comprises silver (Ag) and lithium (Li).

10. The semiconductor device of claim 1, wherein the first source/drain electrode and the second source/drain electrode comprise an adhesive layer and a conductive metal pattern on the adhesive layer,
the adhesive layer comprises chromium, titanium, or a combination thereof, and
the conductive metal pattern comprises gold, aluminum, copper, or a combination thereof.

11. A semiconductor device comprising:
a substrate and an insulating layer on the substrate;
a phase change material structure on the insulating layer; and
a first source/drain electrode and a second source/drain electrode disposed on the phase change material structure and spaced apart from each other in a first direction,
wherein the phase change material structure includes:
a plurality of two-dimensional material layers; and
an intercalation material between the plurality of two-dimensional material layers,
the intercalation material has first to third concentrations, and
the intercalation material exhibits changes in behavior according to the first to
third concentrations.

12. The semiconductor device of claim 11, wherein the intercalation material has the first concentration, and
the phase change material structure has a hexagonal structure (2H structure).

13. The semiconductor device of claim 12, wherein the first concentration is in a range of about 10 at % to about 15 at %.

14. The semiconductor device of claim 11, wherein the intercalation material has the second concentration,
the phase change material structure has a hexagonal structure (2H structure) and a first monoclinic structure (1T′ structure) or a hexagonal structure (2H structure) and a second monoclinic structure (1T structure), and
the intercalation material has a first cluster form.

15. The semiconductor device of claim 14, wherein the second concentration is in a range of about 16 at % to about 20 at %, and
the first cluster form is formed around at least one of the first source/drain electrode or the second source/drain electrode.

16. The semiconductor device of claim 11, wherein the intercalation material has the third concentration,
the phase change material structure has a hexagonal structure (2H structure) and a first monoclinic structure (1T′ structure) or a hexagonal structure (2H structure) and a second monoclinic structure (1T structure), and
the intercalation material has a second cluster form.

17. The semiconductor device of claim 16, wherein the second concentration is in a range of about 21 at % to about 25 at %, and
the second cluster form is a conductive filament connecting the first source/drain electrode and the second source/drain electrode.

18. A method for manufacturing a semiconductor device, the method comprising:
preparing a substrate;
forming an insulating layer on the substrate;
forming a phase change material structure including a two-dimensional material layer on the insulating layer; and
forming a first source/drain electrode and a second source/drain electrode on the phase change material structure,
wherein the forming of the phase change material structure includes:
forming a two-dimensional material layer on the insulating layer;
performing a first intercalation process on the two-dimensional material layer; and
performing a second intercalation process after the first intercalation process, and
the phase change material structure includes two-dimensional material layers and Ag ions between the two-dimensional material layers.

19. The method of claim 18, wherein the performing of the first intercalation process involves inserting Li ions between the two-dimensional material layers.

20. The method of claim 19, wherein the performing of the second intercalation process involves inserting Ag ions between the two-dimensional material layers.
